(19) United States
(12) Patent Application Publication
(10) Pub. No.: US 2022/0199103 A1
(43) Pub. Date: Jun. 23, 2022

(54) METHOD AND SYSTEM FOR IMPROVING QUALITY OF DEGRADED SPEECH

(71) Applicant: Plantronics, Inc., Santa Cruz, CA (US)

(72) Inventors: Benjamin Alvarado Carter, Santa Cruz, CA (US); William Henry Scholtz, Redwood City, CA (US)

(73) Assignee: Plantronics, Inc., Santa Cruz, CA (US)

(21) Appl. No.: 17/550,933

(22) Filed: Dec. 14, 2021

Related U.S. Application Data
(60) Provisional application No. 63/130,247, filed on Dec. 23, 2020.

(51) Int. Cl. G10L 21/0364; G10L 25/60; H04R 3/04

(52) U.S. Cl. CPC G10L 21/0364; H04R 3/04; G10L 25/60

(57) ABSTRACT

A system for processing speech signals includes an audio input device configured to obtain an incoming degraded speech signal and an equalizer configured to be programmed by multiple equalizer parameter sets. The system further includes an equalizer parameterization controller configured to select a first equalizer parameter set to program the equalizer to generate an enhanced speech signal from the incoming degraded speech signal.

### CROSS-REFERENCE TO RELATED APPLICATIONS

This application claims benefit under 35 U.S.C. § 119 to U.S. Provisional Patent Application Ser. No. 63/130,247, filed on Dec. 23, 2020, entitled, “Method and System for Improving Quality of Degraded Speech” and having the same inventor(s). Provisional Patent No. 63/130,247 is assigned to the assignee of the present application and is hereby incorporated by reference into the present application as if fully set forth herein.

### BACKGROUND

Various factors may cause a degradation of the intelligibility of speech. For example, the wearing of a protective face mask or even a common cold may degrade the intelligibility of speech. The degradation may be undesirable not only for a listener, but also for the speaker who may try to compensate for the degradation. In remote communication scenarios such as phone calls, video conference calls, etc., where other factors including the transmission of the audio signal representing the speech may further reduce intelligibility, the degradation may be particularly undesirable.

### SUMMARY

In general, in one aspect of the present disclosure, one or more embodiments relate to a system for processing speech signals. The system includes an audio input device configured to obtain an incoming degraded speech signal and an equalizer configured to be programmed by a plurality of equalizer parameter sets.

The system further includes an equalizer parameterization controller configured to select a first one of the plurality of equalizer parameter sets to program the equalizer to generate an enhanced speech signal from the incoming degraded speech signal.

In another aspect of the present disclosure, one or more embodiments relate to a method of processing speech signals including receiving an incoming degraded speech signal, selecting a first one of a plurality of equalizer parameter sets, and programming an equalizer using the first selected equalizer parameter set. The method further includes equalizing in the equalizer the incoming degraded speech signal according to the first selected equalizer parameter set to generate thereby an enhanced speech signal from the incoming degraded speech signal.

In another aspect of the disclosure, one or more embodiments relate to a system for processing speech signals. The system includes an audio input device configured to obtain an incoming degraded speech signal, an equalizer configured to be programmed by a plurality of equalizer parameter sets, and an equalizer parameterization controller configured to select a first one of the plurality of equalizer parameter sets to program the equalizer to generate an enhanced speech signal from the incoming degraded speech signal. The equalizer parameterization controller includes a classifier configured to classify the incoming degraded speech signal based on a training process that compares reference non-degraded speech signals and reference degraded speech signals.

Other aspects of the disclosure will be apparent from the following description and the appended claims.

### BRIEF DESCRIPTION OF DRAWINGS

Specific embodiments of the disclosure will now be described in detail with reference to the accompanying figures. Like elements in the various figures are denoted by like reference numerals for consistency.

FIG. 1 shows a system for improving quality of degraded speech, in accordance with one or more embodiments of the disclosure.

FIG. 2 shows a signal processing, in accordance with one or more embodiments of the disclosure.

FIG. 3 shows a flowchart describing a method for improving quality of degraded speech, in accordance with one or more embodiments of the disclosure.

FIG. 4 shows a flowchart describing a method for manually parameterizing an equalizer, in accordance with one or more embodiments of the disclosure.

FIG. 5 shows a flowchart describing a method for automatically parameterizing an equalizer, in accordance with one or more embodiments of the disclosure.

FIG. 6 shows a flowchart describing a method for determining an equalizer parameter set, in accordance with one or more embodiments of the disclosure.

### DETAILED DESCRIPTION

In general, embodiments of the disclosure improve quality of degraded speech. Various factors may cause a degradation of speech. For example, the wearing of a protective mask during a pandemic, a common cold, or other impairments may degrade speech.

The degradation may be undesirable not only for a listener, but also for the speaker who may try to compensate for the degradation. In remote communication scenarios such as phone calls, video conference calls, etc., where other factors, including the transmission of the audio signal representing the speech may limit the quality of the speech, the degradation may be particularly undesirable.

In one particular example, headset users in crowded environments, e.g., in call centers or offices may wear face masks to reduce the risk associated with airborne pathogens. The face mask may distort the transmission of speech. More specifically, a vocal transmission loss (or gain, when resonances occur) due to the face mask may cause distortions. Different types of face masks may cause different distortions. For example, N95 respirators, disposable face masks, cloth face masks, neck gaiters, and other masks covering the mouth and/or nose attenuate speech energy primarily via acoustic transmission loss through the face mask material, although to different degrees. Some face masks may also slightly restrict the nasal cavity, causing further attenuation and/or coloration. The attenuation yields a muffled voice quality presented to microphone(s) on a headset, handset, or speakerphone, resulting in a perceived poor quality, and/or reduced speech intelligibility on the far end.

In one or more embodiments, a degraded speech signal is processed to compensate, at least partially, for the degradation. In a configuration involving a local party using a local audio device, and a remote party using a remote audio device, the compensation may be performed on the local audio device, thereby improving the quality of the speech signal being transmitted to the remote audio device. The compensation may be able to handle different distortions, such as the different distortions associated with different types of face masks.

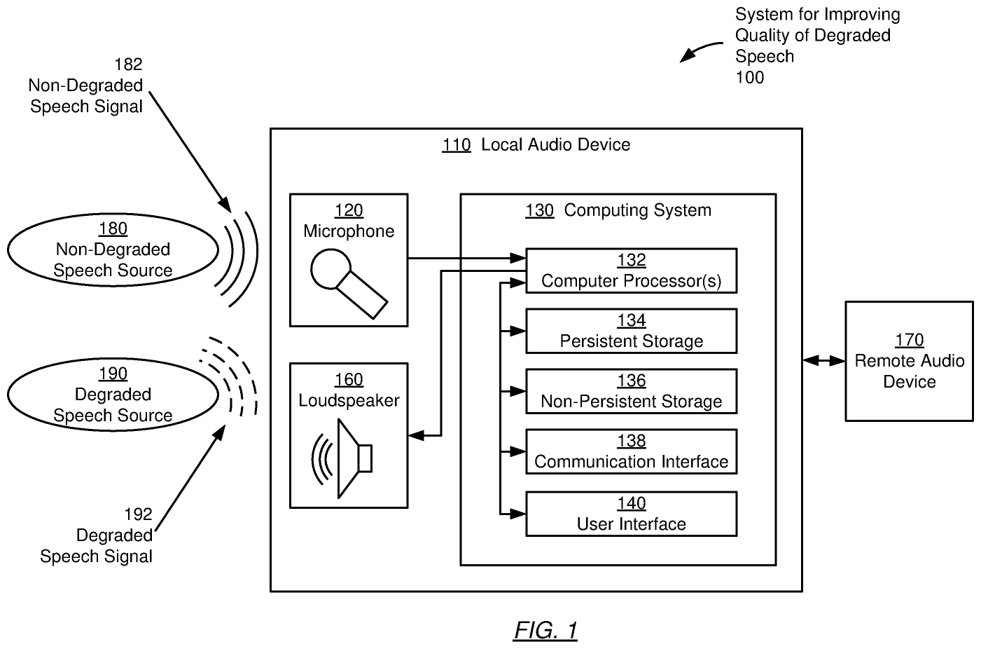

Turning to FIG. 1, a system (100) for improving quality of degraded speech, in accordance with one or more embodiments of the disclosure, is shown. The system (100) may include a local audio device (110) that may interface with a remote audio device (170). The local audio device (110) may include a microphone (120), a computing system (130), and may further include a loudspeaker (160). Each of these components is subsequently described. The local audio device (110) may be any kind of communication device such as a headset, a speakerphone, an audio-conferencing device, a video conferencing device, etc. Alternatively, the local audio device (110) may be an audio recording device.

The microphone (120) is configured to capture real-time audio signals. The audio signals may be speech signals, and the microphone (120) may be optimized for capturing speech. An array of microphones may be used to enable speaker localization. More generally, any audio input device may be used, including a storage device that stores recorded audio signals. The audio input device may be any type of audio source. The microphone (120) may be part of a headset, the microphone may be integrated into the body of a communication device or recording device, or the microphone may be detached from other components of the local audio device (110). The audio signals captured by the microphone (120) may be non-degraded speech signals (182) originating from a non-degraded speech source (180) and/or degraded speech signals (192) originating from a degraded speech source (190). In one example, the non-degraded speech source (180) is a speaker not wearing a face mask or other speech-impairing accessory, whereas the degraded speech source (190) is a speaker wearing a face mask or other speech-impairing accessory.

The loudspeaker (160) is configured to provide audio output. The audio output may be for a user or multiple users, e.g., when participating in a phone call. One or more loudspeakers (160) may be used. The loudspeaker (160) may be part of a headset, the loudspeaker may be integrated into the body of a communication device or recording device, or the loudspeaker may be detached from other components of a device.

In one or more embodiments, the local audio device (110) includes a computing system (130). The computing system (130) may include various components such as one or more computer processors (132), persistent storage (134), non-persistent storage (136) a communication interface (138), and a user interface (140).

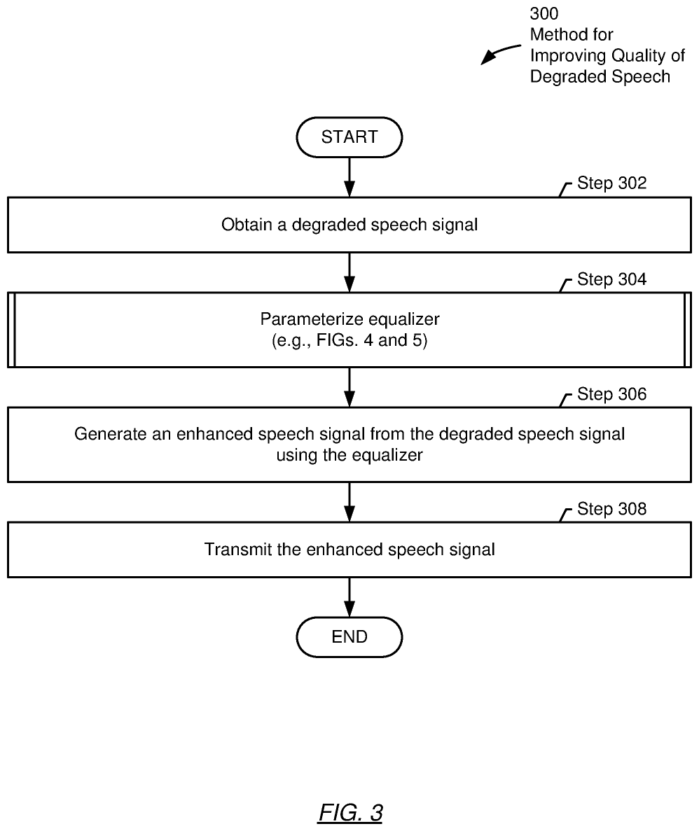

The one or more computer processors (132) may include one or more integrated circuits for processing instructions. For example, the computer processor(s) (132) may be one or more cores or micro-cores of a processor. The one or more computer processors (132) may include a digital signal processor (DSP). The computer processor (132) may process audio signals received from the microphone (120), e.g., to improve quality of degraded speech by executing one or more of the instructions described below in reference to the flowcharts of FIGS. 3-6. In addition, the computer processor (132) may also perform operations to output an audio signal by the loudspeaker (160), e.g., when receiving audio data via the communication interface (138). The computer processor (132) may further execute an operating system and may be involved in various tasks such as communications with other devices via the communication interface (138).

The persistent storage (134) may be a hard disk, an optical drive such as a compact disk (CD) drive or digital versatile disk (DVD) drive, a flash memory, etc., storing, for example, the operating system, and instructions, e.g., instructions implementing one or more of the steps of the methods described below in reference to the flowcharts of FIGS. 3-6. In some embodiments, the persistent storage (134) may store recorded audio signals of degraded speech and/or non-degraded speech that is processed by computer processor (132) in accordance with the principles of the present disclosure.

The non-persistent storage (136) may be volatile memory, such as random-access memory (RAM) and/or cache memory, used when executing the steps of the methods described below.

The communication interface (138), in one or more embodiments, may include, for example, a network interface (such as an Ethernet, WLAN or Bluetooth interface) and/or a telephone network interface (such as a public switched telephone network (PSTN) interface). Any type of communication interface that allows the transmission of audio signals in digital or analog format may be used. In case of the local audio device (110) operating as a communication device, audio signals, picked up by the microphone (120) and processed by the computing system (130), may be sent to another remote audio device (170) via the communication interface (138), and audio signals from the remote audio device (170) may be received via the communication interface (138) and output by the loudspeaker (160).

The user interface (140), in one or more embodiments, enables the user (e.g., a speaker) to control at least some of the operations of the system (100), as discussed below. The user interface (140) may be a hardware user interface including, for example, various control buttons, a display, etc. The user interface (140) may also be a software user interface, e.g., a graphical user interface with virtual control and/or display elements.

While FIG. 1 shows a configuration of components, other configurations may be used without departing from the scope of the disclosure. For example, the local audio device (110) may be configured to operate as a stand-alone unit, or it may be integrated into another device such as a desktop or laptop computing device, a headset, etc. In one embodiment, the local audio device (110) includes a hub, e.g., in the form of a desktop unit, and one or more headsets interfacing with the hub. The hub may include the computing system (130) and may further include the user interface (140). The local audio device (110) may also include additional hardware and/or software components, not shown in FIG. 1. For example, the local audio device may include analog-to-digital and/or digital-to analog converters, and/or other components.

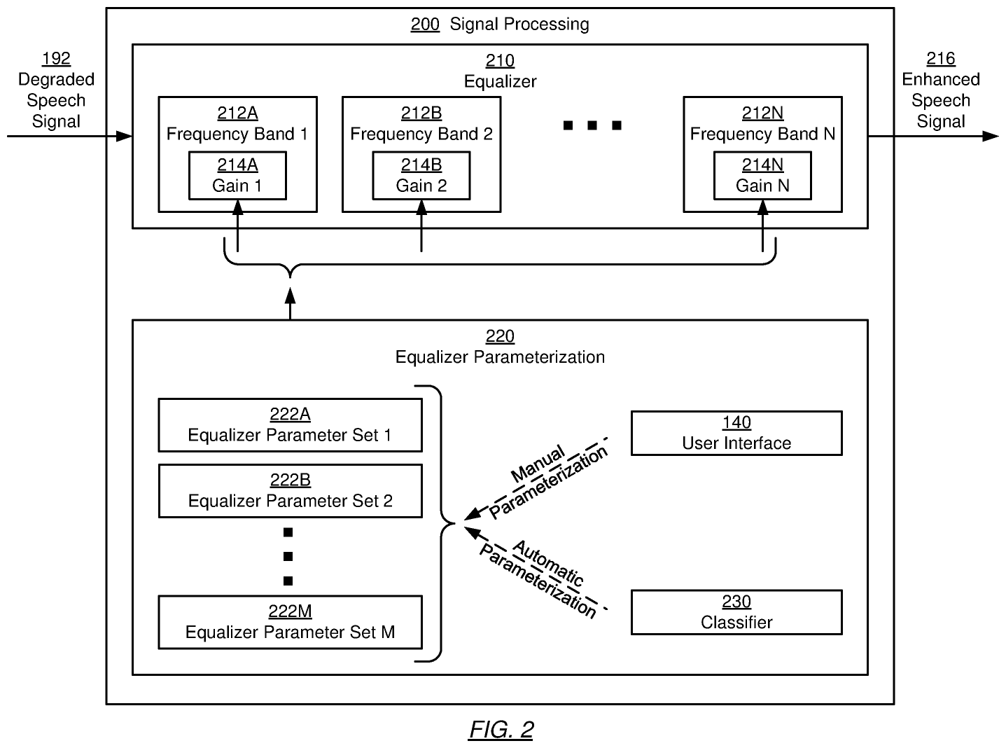

Turning to FIG. 2, a signal processing, in accordance with one or more embodiments of the disclosure, is shown. The signal processing (200) may be performed by components of the computing system (130) of FIG. 1. While the operations performed by the computing system (130) are in the digital domain, at least some of the operations may also be performed in the analog domain.

The signal processing (200) may be performed by an equalizer (210). The equalizer (210) may operate on the degraded speech signal (192) to generate an enhanced speech signal (216). The enhanced speech signal (216) may be the degraded speech signal (192), adjusted for the degradation, by the equalizer (210). While the adjustment by the equalizer may not entirely compensate for the degradation, the enhanced speech signal (216) contains less of the degradation than the degraded speech signal (192). The degradation of the degraded speech signal (192) may be non-uniform across frequencies. In one or more embodiments, the equalizer (210) operates in different frequency bands (212A-212N) to compensate for the degradation in a frequency-specific manner. The overall frequency range that is processed by the equalizer (210) may cover the frequency range associated with human speech. The equalizer may process, for example, frequencies in the range of 80 Hz to 16 kHz, or 80 Hz to 8 kHz. Other frequency ranges may be used, without departing from the disclosure. The frequency bands (212A-212N) may split the frequency range, for example, into one-third octave frequency bands, full octave bands, etc. The equalizer may include biquadratic (biquad) filters or any other types of filters implementing the frequency bands (212A-212N). For each of the frequency bands (212A-212N), the equalizer may provide a gain (214A-214N) that may amplify or attenuate the degraded speech signal (192) within the corresponding frequency band.

In one or more embodiments, the gains (214A-214N) for the frequency bands (212A-212N) are set by an equalizer parameterization controller 220. The equalizer parameterization controller 220 may operate using multiple equalizer parameter sets (222A-222M). One of the multiple equalizer parameter sets (222A-222M) may be chosen to parameterize the equalizer. The parameterization may be performed by setting the gains (214A-214N) according to the chosen equalizer parameter set. Thus, each of the equalizer parameter sets (222A-222M) includes gain values for the gains (214A-214N).

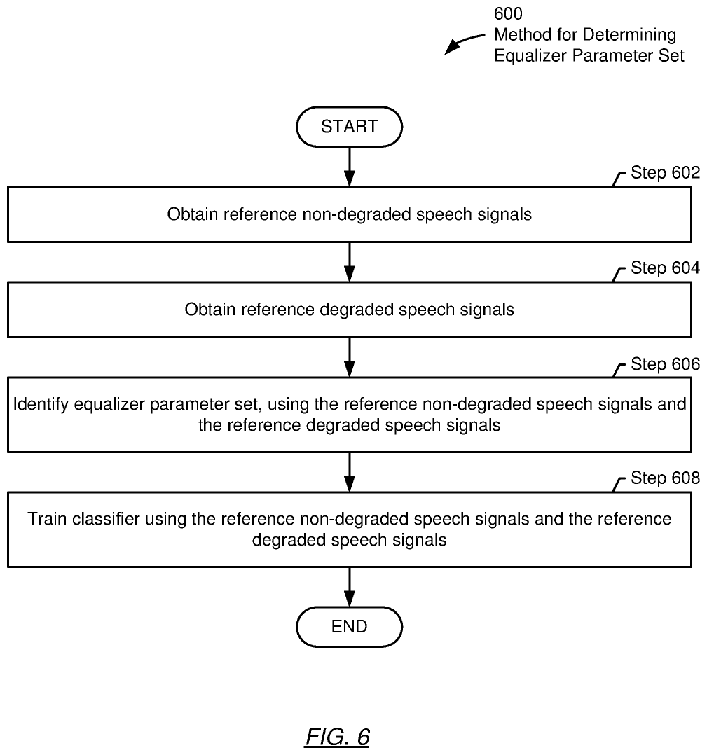

Each of the equalizer parameter sets (222A-222M) may be specific to a particular degraded speech scenario. Assume, for example, that the signal processing (200) is for processing of a degraded speech signal (192) that is a result of the speaker wearing a face mask. In this scenario, vocal transmission loss characteristics of various face mask types may be different depending on the type of face mask. For example, an attenuation across the frequency bands (212A-212N) may be different depending on whether the speaker wears an N95 respirator or a cloth mask. Accordingly, there may be an equalizer parameter set that is specific to N95 respirators, and an equalizer parameter set that is specific to the cloth mask. FIG. 6 describes a method for determining an equalizer parameter set. When properly chosen, the gains in an equalizer parameter set may adjust the degraded speech signal to at least partially compensate for the attenuated vocal energy and thus improve or enhance transmit quality.

The parameterization of the equalizer may involve programming the equalizer with the gains of the chosen parameter set. The parameterization may be manually or automatically performed, as discussed below in reference to the flowcharts of FIGS. 3, 4, and 5. A manual parameterization may be performed by a user via the user interface (140). An automatic parameterization may be performed by a classifier (230) operating on the degraded speech signal (192).

While FIG. 2 shows a signal processing as it may be used to improve the quality of degraded speech, additional types of signal processing may be performed without departing from the scope of the disclosure. For example, the signal processing of FIG. 2 may be integrated with signal processing configured to reduce transmit channel noise, perform speech localization, perform spatial and/or temporal filtering, etc.

FIGS. 3, 4, 5, and 6 show flowcharts in accordance with one or more embodiments of the disclosure. While the various steps in these flowcharts are provided and described sequentially, one of ordinary skill will appreciate that some or all of the steps may be executed in different orders, may be combined or omitted, and some or all of the steps may be executed in parallel. Furthermore, the steps may be performed actively or passively. For example, some steps may be performed using polling or be interrupt driven in accordance with one or more embodiments of the disclosure. By way of an example, determination steps may not require a processor to process an instruction unless an interrupt is received to signify that condition exists in accordance with one or more embodiments of the disclosure. As another example, determination steps may be performed by performing a test, such as checking a data value to test whether the value is consistent with the tested condition in accordance with one or more embodiments of the disclosure. The flowcharts of FIGS. 3, 4, and 5 describe various operations performed to improve the quality of degraded speech, in accordance with one or more embodiments. The flowchart of FIG. 6 describes operations that may be performed to obtain equalizer parameter sets, in accordance with one or more embodiments. The equalizer parameter sets obtained as described in FIG. 6 may be used by the methods of FIGS. 3, 4, and 5.

Turning to FIG. 3, a flowchart describing a method for improving the quality of degraded speech (300), in accordance with one or more embodiments, is shown.

In Step 302, a degraded speech signal is obtained. The degraded speech signal may be obtained using a microphone, e.g., as shown in FIG. 1. Alternatively, the degraded speech signal may be obtained from elsewhere, e.g., from a recording. The obtaining of the degraded speech signal may further include additional steps such as and analog-to-digital conversion.

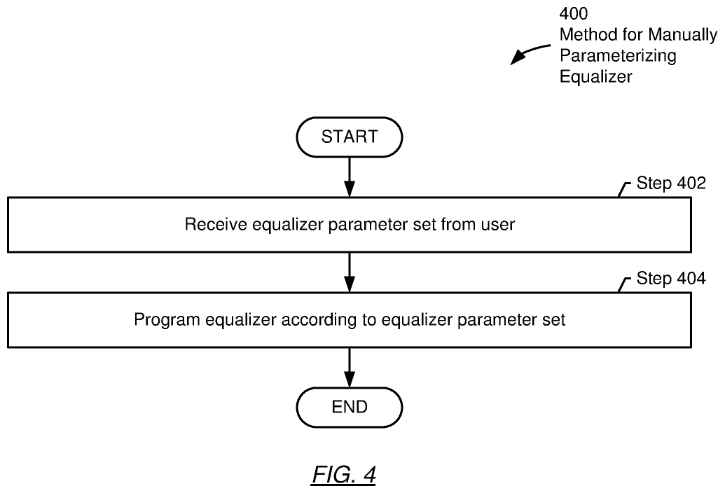

In Step 304, the equalizer is parameterized. The parameterizing of the equalizer may involve setting gains for the frequency bands of the equalizer. The parameterizing of the equalizer may be performed in different manners, e.g., manually by a user (discussed below in reference to FIG. 4), or automatically by the system itself (discussed below in reference to FIG. and 5). In case of an equalizer that includes a set of filters (e.g., one filter per frequency band), the parameterizing of the equalizer may involve parameterizing the filters with the gains. While the parameterizing of the equalizer, in FIG. 3 is shown as being performed in Step 304, following Step 302, the order of these steps may be different, without departing from the disclosure. For example, when the parameterization is manually performed (described in reference to FIG. 4), the parameterization may occur at any time, whenever the user, e.g., the speaker, decides to change the parameterization.

In Step 306, an enhanced speech signal is generated by the equalizer processing the degraded speech signal. The equalizer may operate on the degraded speech signal in the frequency bands of the equalizer, applying the gains set in Step 304. The application of the gains to the degraded speech signal may be performed in operations that are performed separately from other operations (e.g. by passing the degraded speech signal through the filters implementing the frequency bands of the equalizer) after setting the gains in Step 304. Alternatively, the operation of the equalizer on the degraded speech signal may be combined with other operations, without departing from the disclosure. For example, various types of noise reduction may be performed on the degraded speech signal, a bandwidth compression or expansion may be performed on the degraded speech signal, etc.

In Step 308, the enhanced speech signal is transmitted. When used in a scenario involving a phone call or conference call, the enhanced speech signal may be transmitted to a remote audio device. The enhanced speech signal may alternatively be transmitted to elsewhere, e.g., to a recording device.

Turning to FIG. 4, a flowchart describing a method for manually parameterizing an equalizer (400), in accordance with one or more embodiments, is shown. After the execution of the method (400), the equalizer may be parameterized to produce an enhanced speech signal from the degraded speech signal. The parameterization may be performed to address a particular type of degradation (e.g., as a result of the speaker very a particular type of face mask), or alternatively, to handle non-degraded speech.

In Step 402, an equalizer parameter set is obtained from the user. The equalizer parameter set may be obtained in various different ways. For example, the user (who may be the speaker) may manually tune the equalizer. A user interface may receive tuned equalizer parameters from the user. For example, a graphical user interface may provide a visualization of the equalizer, with tunable sliders for the gains in frequency bands of the equalizer.

In one embodiment, the user picks an equalizer parameter set from multiple equalizer parameter sets. The multiple equalizer parameter sets may be stored in a non-volatile or volatile memory. Each of the multiple equalizer parameter sets may have previously been identified as described in reference to FIG. 6. Each of the multiple equalizer parameter sets may be for a particular degradation of a speech signal. For example, a first equalizer parameter set may be designed to compensate for degradations of the speech signal associated with wearing an N95 respirator, a second equalizer parameter set may be designed to compensate for degradations of the speech signal associated with a cloth mask, etc. A user interface may provide selectors allowing the user to pick one of the multiple equalizer parameter sets to parameterize the equalizer. The user interface may be a software user interface, or a hardware user interface, e.g., including physical buttons on the local audio device. The user interface may also be a voice-controlled user interface, responding to spoken commands.

In Step 404, the equalizer is programmed according to the equalizer parameter set picked by the user. The programming may involve adjusting gains for one or more of the frequency bands of the equalizer. The adjusting of the gains may be performed by updating the coefficients of the filters associated with the frequency bands. The adjusting of the gains may also involve unit conversions. For example, a gain provided as part of the equalizer parameter set may be specified in decibel (dB), which may be converted to filter coefficients suitable to adjust the gain of the filter implementing the corresponding frequency band.

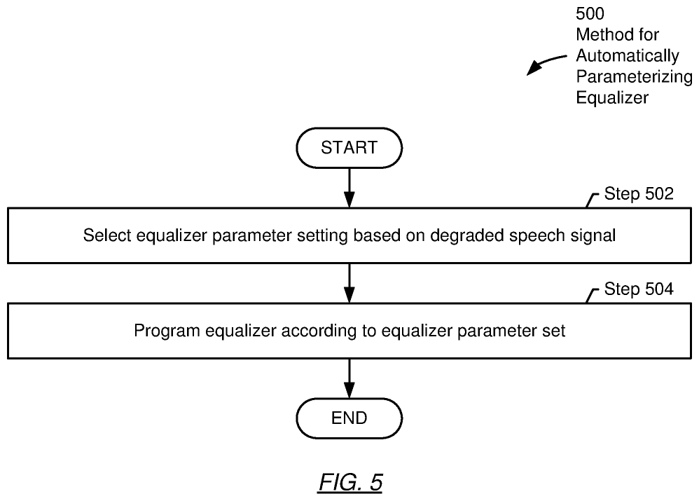

Turning to FIG. 5, a flowchart describing a method for automatically parameterizing an equalizer (500), in accordance with one or more embodiments, is shown. After the execution of the method (500), the equalizer may be parameterized to produce an enhanced speech signal from the degraded speech signal. The parameterization may be performed to address a particular type of degradation (e.g., as a result of the speaker wearing a particular type of face mask), or alternatively to handle non-degraded speech.

In Step 502, an equalizer parameter set is selected. The equalizer parameter set, in one or more embodiments, is selected based on the degraded speech signal. The equalizer parameter set may be selected from multiple equalizer parameter sets. The multiple equalizer parameter sets may be stored in a non-volatile or volatile memory. Each of the multiple equalizer parameter sets may have previously been generated as described in reference to FIG. 6. Each of the multiple equalizer parameter sets may be for a particular degradation of a speech signal. For example, a first equalizer parameter set may be designed to compensate for degradations of the speech signal associated with wearing an N95 respirator, a second equalizer parameter set may be designed to compensate for degradations of the speech signal associated with a cloth mask, etc.

The selection of the equalizer parameter set to be used for programming the equalizer may be performed using methods of statistical analysis, e.g., using a classifier (230). The classifier (230) may be used to perform the selection of the equalizer parameter set to be used for programming the equalizer from the multiple equalizer parameter sets. The classification task may be performed in the frequency domain, e.g., using spectrum analysis for the frequency bands of the equalizer. Specifically, a frequency spectrum, obtained for the degraded speech signal may be compared to previously obtained frequency spectra of degraded speech. In one embodiment, the classifier 230 may select an equalizer parameter set based on simple frequency-band level comparison (or subtraction) to see if an equalizer parameter set has a similar curve to an incoming degraded speech signal. The comparison may be weighted for importance due to enhanced speech intelligibility, specifically at 2 kHz, In another embodiment, the classifier 230 may select an equalizer parameter set based on a curve-fitting operation between the incoming degraded speech signal and one or more internal equalizer sets. The classifier 230 may select an equalizer parameter set using the same operations on a reference non-degraded speech signal.

Assume, for example, that a first equalizer parameter set is designed to compensate for degradations of the speech signal associated with wearing an N95 respirator, a second equalizer parameter set is designed to compensate for degradations of the speech signal associated with a cloth mask, etc. Accordingly, the first equalizer parameter set is associated with a frequency spectrum typical for degraded speech resulting from wearing an N95 respirator. The second equalizer parameter set is associated with a frequency spectrum typical for degraded speech resulting from wearing a cloth mask. A comparison of the frequency spectrum obtained for the degraded speech with the frequency spectra associated with the multiple equalizer parameter sets is performed to identify the equalizer parameter set associated with one of the frequency spectra that is most similar. Thus, the comparison may allow identification of a parameter set for which the associated frequency spectrum is most similar to the frequency spectrum of the degraded speech, in comparison to other frequency spectra. The comparison may be implemented in the form of a classification task using, for example, neural networks, k-nearest neighbors, Naïve Bayes, decision trees, support vector machines, or other algorithms. Prior to execution of Step 502, the classification algorithm may have been trained as described in reference to FIG. 6.

In Step 504, the equalizer is programmed according to the equalizer parameter set picked by the user. The programming may involve adjusting gains for one or more of the frequency bands of the equalizer. The adjusting of the gains may be performed by updating the coefficients of the filters associated with the frequency bands. The adjusting of the gains may also involve unit conversions. For example, a gain provided as part of the equalizer parameter set may be specified in decibel (dB), which may be converted to filter coefficients suitable to adjust the gain of the filter implementing the corresponding frequency band.

Turning to FIG. 6, a flowchart describing a method for determining an equalizer parameter set (600), in accordance with one or more embodiments, is shown. The method of FIG. 6 may be executed for each equalizer parameter set that may be used by the methods of FIGS. 3, 4, and 5.

In Step 602 and 604, reference non-degraded speech signals and reference degraded speech signals, respectively, are obtained. The non-degraded speech signals and the degraded speech signals may be obtained from a single speaker, to perform the subsequently discussed operations in a speaker-specific manner. Alternatively, the non-degraded speech signals and the degraded speech signals may be obtained from multiple speakers to perform the subsequently discussed operations for a broader base of speakers. The non-degraded speech signals and the degraded speech signals may include recorded speech samples. The recorded speech samples may include spoken sentences. The speaker may be asked to speak sentences at different volumes, different speeds, etc. One or more speakers may be involved in performing Step 604 while wearing different types of face masks. Further, one or more speakers may be involved in performing Step 602 while not wearing a face mask. Accordingly, after completion of Steps 602 and 604, non-degraded speech signals (speaker(s) not wearing a face mask) and degraded speech signals for the different types of face masks (speaker(s) wearing the corresponding face masks) may be available.

In Step 606, an equalizer parameter set is generated. The equalizer parameter set may be specific to a particular type of degraded speech signal. For example, one equalizer parameter set may be specific to the speaker wearing an N95 respirator, whereas another equalizer parameter set may be specific to the speaker wearing a cloth face mask. Accordingly, Step 606 may be repeated to obtain different equalizer parameter sets for different types of degraded speech signals. The equalizer parameter set may be generated by determining a transmission loss (reference degraded speech signal vs reference non-degraded speech signal) in the frequency bands of the equalizer. The signal energies in the frequency bands may be used to determine the transmission loss. Based on the detected transmission loss, the gains may be selected. In one embodiment, a gain for a frequency band is selected such that the gain compensates for the transmission loss. As an alternative to using reference non-degraded speech signals to determine the gains, a minimum quality threshold may be applied. The minimum quality threshold may establish a signal energy for each of the frequency bands. The minimum quality threshold may have been obtained based on speech samples that have been averaged. The speech samples may have been categorized to match certain desired characteristics (for example, having a high degree of intelligibility). The gains may then be selected such that the minimum quality threshold is reached by the enhanced speech signal based on the amplification (or attenuation) of the degraded speech signal as specified by the gains. The gains may be further adjusted by other operations that are not necessarily directly related to the method for improving quality of degraded speech. For example, operations such as noise suppression may also tweak the gains of the equalizer.

While Steps 602-606 may be performed offline, e.g. during a calibration phase, at least some of the described operations may also be performed online during execution of the method described in FIG. 3, to continuously tune the equalizer by adjusting the gains.

The online tuning of gains may be performed based on far-end feedback from a receiving side. Consider, for example, a scenario in which, in a telephone conference call, the enhanced speech signal is provided to a remote participant. The remote participant may provide feedback on the perceived speech quality. For example, the remote participant may indicate that the local participant (the speaker) sounds muffled. Based on this feedback, the gains may be adjusted. Methods of natural language processing and machine learning may be used to receive the feedback and to make the gain adjustments. Instead of the remote participant providing feedback, objective test measures for a Mean Opinion Score (MOS), such as 3QUEST or POLQA may also be used to measure speech quality delivered to the remote participant at the far end.

The online tuning of gains may also be performed based on local feedback. The local feedback may be based on an analysis of the enhanced speech signal, obtained from the equalizer. A real-time statistical spectrum analysis may be performed to determine whether the enhanced speech signal meets certain requirements. For example, the previously described minimum quality threshold may be used for the analysis, and the gains may be adjusted over time, until the minimum quality threshold is reached.

In Step 608, a classifier is trained. In one or more embodiments, the classifier is trained to distinguish the scenarios that would trigger the selection of particular equalizer parameter sets. For example, the classifier may be trained to identify whether a speaker wears no face mask, an N95 respirator, or a cloth mask, based on the speech signal obtained from the speaker. The training may be performed using the reference degraded and non-degraded speech signals as previously described. A supervised training approach may be used to train the classifier. The specifics of the training depends on the type of classifier being used. The training may be applicable to neural networks, k-nearest neighbors, Naïve Bayes, decision trees, support vector machines, or other algorithms that may be used.

Embodiments of the disclosure may be used to enhance the quality of a degraded speech signal, resulting from, for example, a speaker wearing a mask. Unlike commonly used equalizers that operate on the receiving side (e.g., an equalizer of a music playback device), embodiments of the disclosure use equalizers on the transmitting side. Accordingly, any remote user, regardless of the equipment on the receiving side, may benefit from the enhanced quality of the speech signal, provided by the equalizer on the transmitting side. Embodiments of the disclosure are applicable to any degraded speech signal and may be particularly beneficial for enhancing speech signals that are degraded as a result of the speaker wearing a face mask.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A system (100) for processing speech signals, the system (100) comprising:
an audio input device (110) configured to obtain an incoming degraded speech signal;
an equalizer (210) configured to be programmed by a plurality of equalizer parameter sets (222); and
an equalizer parameterization controller (220) configured to select a first equalizer parameter set (222) of the plurality of equalizer parameter sets (222) to program the equalizer (210) to generate an enhanced speech signal from the incoming degraded speech signal.

2. The system (100) of claim 1, wherein the equalizer parameterization controller (220) selects the first equalizer parameter set (222) based on a comparison of a frequency spectrum of the incoming degraded speech signal with a frequency spectrum associated with the first equalizer parameter set (222).

3. The system (100) of claim 2, wherein the first equalizer parameter set (222) is generated based on a comparison of a reference non-degraded speech signal and a reference degraded speech signal.

4. The system (100) of claim 3, wherein the reference non-degraded speech signal and the reference degraded speech signal are obtained from a single speaker.

5. The system (100) of claim 3, wherein the reference non-degraded speech signal and the reference degraded speech signal are obtained from multiple speakers.

6. The system (100) of claim 3, wherein the reference non-degraded speech signal comprises a minimum quality threshold.

7. The system (100) of claim 6, wherein the minimum quality threshold is based on an average of a plurality of speech samples.

8. The system (100) of claim 1, wherein the incoming degraded speech signal may comprise one of i) a real-time audio signal received from a microphone (120) or ii) a recorded audio signal received from a storage device.

9. A method of processing a degraded speech signal comprising:
selecting a first equalizer parameter set (222) of a plurality of equalizer parameter sets (222);
programming an equalizer (210) using the first selected equalizer parameter set; and
equalizing in the equalizer (210) the degraded speech signal according to the first selected equalizer parameter set (222) to generate thereby an enhanced speech signal from the incoming degraded speech signal.

10. The method of claim 9, wherein selecting the first equalizer parameter set (222) is based on a comparison of a frequency spectrum of the incoming degraded speech signal with a frequency spectrum associated with the first equalizer parameter set (222).

11. The method of claim 10, wherein the first equalizer parameter set (222) is generated based on a comparison of a reference non-degraded speech signal and a reference degraded speech signal.

12. The method of claim 11, wherein the reference non-degraded speech signal and the reference degraded speech signal are obtained from a single speaker.

13. The method of claim 11, wherein the reference non-degraded speech signal and the reference degraded speech signal are obtained from multiple speakers.

14. The method of claim 11, wherein the reference non-degraded speech signal comprises a minimum quality threshold.

15. The method of claim 14, wherein the minimum quality threshold is based on an average of a plurality of speech samples.

16. The method of claim 9, wherein the incoming degraded speech signal may comprise one of i) a real-time audio signal received from a microphone or ii) a recorded audio signal received from a storage device.

17. A system (100) for processing speech signals, the system (100) comprising:
an audio input device configured to obtain an incoming degraded speech signal;
an equalizer (210) configured to be programmed by a plurality of equalizer parameter sets (222); and
an equalizer parameterization controller configured to select a first equalizer parameter set (222) of the plurality of equalizer parameter sets (222) to program the equalizer (210) to generate an enhanced speech signal from the incoming degraded speech signal,
wherein the equalizer parameterization controller comprises a classifier configured to classify the incoming degraded speech signal based on a training process that compares reference non-degraded speech signals and reference degraded speech signals.

18. The system (100) of claim 17, wherein the classifier selects the first equalizer parameter set (222) based on a comparison of a frequency spectrum of the incoming degraded speech signal with a frequency spectrum associated with the first equalizer parameter set (222).

19. The system (100) of claim 18, wherein the reference non-degraded speech signals and the reference degraded speech signals are obtained from a single speaker.

20. The system (100) of claim 18, wherein the reference non-degraded speech signals and the reference degraded speech signals are obtained from multiple speakers.
